(19) United States
(12) Patent Application Publication
(10) Pub. No.: US 2007/0153450 A1
(43) Pub. Date: Jul. 5, 2007

(54) Electronic devices and associated covers

(76) Inventor: Simon Wilson, Berkshire (GB)

Correspondence Address: HARRINGTON & SMITH, PC, 4 RESEARCH DRIVE, SHELTON, CT, 06484-6212, US

(21) Appl. No.: 10/585,179

(22) PCT Filed: Dec. 23, 2004
(86) PCT No.: PCT/EP04/14745

§ 371 Date: Dec. 20, 2006

(30) Foreign Application Priority Data
Dec. 29, 2003 (EP) 0330100.9

(51) Int. Cl. H05K 7/00

(52) U.S. Cl. 361/679; 361/616; 361/667

(57) ABSTRACT

An electronic device cover formed from a sheet of material dimensioned to at least partially cover an electronic device, wherein the sheet is configured to have a substantially flat configuration and a folded configuration and be bendable into the folded configuration to cover the electronic device.

### FIELD OF THE INVENTION

The present invention relates to a cover or housing for an electronic device, and an appropriately modified electronic device to receive the cover or housing. For consistency, the term cover will be used throughout the specification.

Specific embodiments of the present invention relate to mobile communications devices, such as mobile phones, and associated covers. The term mobile phone is used to cover Personal Digital Assistants (PDAs) and electronic devices with mobile phone functionality. Therefore, the mobile phone functionality in a “mobile phone” according to the present invention may be a major/primary or minor/secondary function of the mobile phone. The mobile phone may have additional functionality including, but not limited to, the ability to take still/video images.

The invention is also applicable to other forms of portable electronic devices including portable digital music players, such as MP3 players, personal digital organisers, calculators, and currency converters. Such devices may or may not have mobile phone functionality.

The invention is particularly useful for electronic devices (whether or not portable), which would benefit from having a replaceable cover which could be used to provide a changeable user interface.

For simplicity, the foregoing text will focus on mobile phones.

### BACKGROUND TO THE INVENTION

Known mobile telephones include front (A) and back (B) covers which are made from injection moulded plastic. The A and B covers may be decorated in the mould or painted after removal from the mould.

Some mobile phone covers are user-replaceable and allow a user to personalise their phone by attaching an individualised cover.

Specific embodiments of the present invention provide a mobile phone in which the conventional A and B covers are supplemented or replaced by a single printed decorated foil that is folded and slid into a specially designed chassis.

### SUMMARY OF THE INVENTION

According to a first aspect, there is provided an electronic device cover formed from a sheet of material dimensioned to at least partially cover an electronic device, wherein the sheet is configured to have a substantially flat configuration and a folded configuration and be bendable into the folded configuration to cover the electronic device.

According to a second aspect, there is provided a method of distributing a printed publication with a cover, the cover formed from a sheet of material dimensioned to at least partially cover an electronic device, wherein the sheet is configured to have a substantially flat configuration and a folded configuration and be bendable into the folded configuration to cover the electronic device.

According to a third aspect, there is provided an electronic device arranged to receive an electronic device cover formed from a sheet of material dimensioned to at least partially cover the electronic device, wherein the sheet is configured to have a substantially flat configuration and a folded configuration and be bendable into the folded configuration to cover the electronic device.

According to a fourth aspect, the present invention provides a user replaceable cover for a mobile communications device, comprising a substantially flat plastics sheet member bendable to extend from one side of a mobile communications device to a substantially opposite side.

The sheet member may be adapted to fold over a predetermined folding line to conform to the shape of the mobile communications device.

The sheet member may have been printed to comprise a character for an input means.

The sheet member may have been printed to provide a decorative effect.

The sheet member may have been made of a substantially transparent material and printed from a reverse side.

The sheet member may comprise an embossed portion providing a key cap for the mobile telephone. The embossed portion may have been labelled by a character printed directly onto the sheet member.

The sheet member may have been configured to cover the mobile communications device in a U shape so that the sheet member covers substantially two opposite sides of the mobile communications device.

The cover may have a reeled configuration for facilitating transport, storage and/or packaging of the cover.

The sheet member may comprise adhesive material on a reverse side configured to attach to the mobile communication device.

According to a fifth aspect, the present invention provides a mobile communications device comprising means for reversible attaching a user replaceable cover according to any of the preceding claims onto two substantially opposite sides of the mobile communications device.

According to a sixth aspect, the present invention provides a method of providing a user replaceable cover comprising bending a substantially flat plastics sheet member such that it is capable to extend from one side of a mobile communications device to a substantially opposite side.

According to a seventh aspect, the present invention provides a mobile communications device comprising a body having major front and back surfaces separated by at least one edge surface, and a unitary cover member extending over the front, edge and back surfaces of the body.

The body may include a plurality of edge surfaces and the unitary cover member extends over only one of the edge surfaces.

The unitary cover member may be formed by folding a planar member.

The unitary cover member may be removable.

The unitary cover member may be removed by sliding the cover along grooves on the front and/or back surfaces of the body.

The front surface of the body may includes a keypad and/or a display.

The present invention provides preferred embodiments for each of the aspects of the invention corresponding to appropriately modified preferred embodiments of one or more of the other aspects of the invention.

### BRIEF DESCRIPTION OF FIGURES

Specific embodiments of the present invention will be described, by way of example only, with reference to the following figure in which:

FIG. 1 provides a perspective view of aspects of embodiments according to the present invention;

FIG. 1a illustrates a folded cover and mobile phone according to the present invention; and

FIG. 1b illustrates a pre-folded flat mobile phone cover according to the present invention.

### DETAILED DESCRIPTION OF SPECIFIC EMBODIMENTS

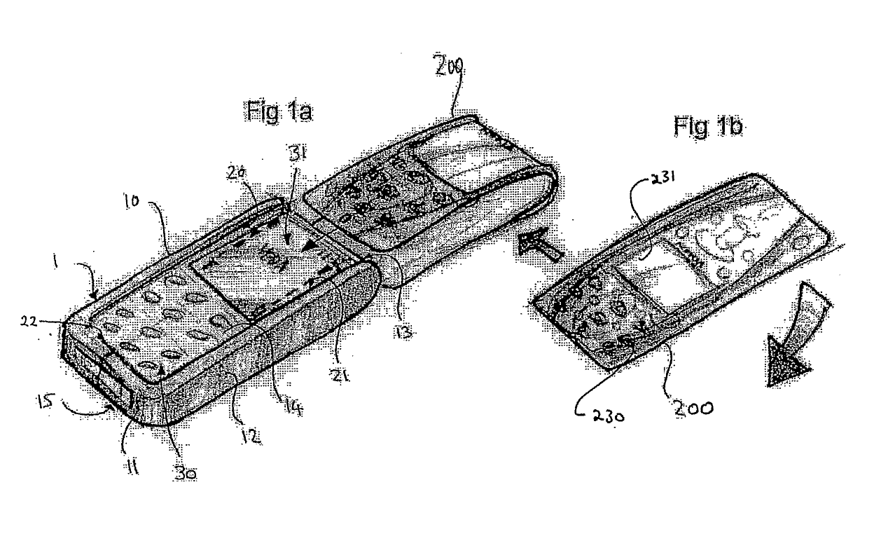

An embodiment of the invention is shown in FIGS. 1a and 1b. FIG. 1a shows the body 1 of a mobile telephone and a cover member 200 about to be slid over the body 1. FIG. 1b shows the cover 200 (or foil) in a flat un-folded state.

As shown in FIG. 1a, preferably the body 1 includes a plurality of edge surfaces 10, 11, 12, 13 and the unitary cover member 200 extends over only one of the edge surfaces 13.

The unitary cover member 200 of FIG. 1a is formed by folding the planar member of FIG. 1b in half. As shown in FIG. 1b, the planar member 200 may be decorated before being folded. The planar member is folded back on itself and defines a U shape. The cover 200 is folded such that it would unfold into the flat configuration if it were not held.

The planar member 200 may be screen printed and embossed, and may be trimmed using simple and inexpensive 2-dimensional cutting tools. Alternatively, the unitary cover member 200 may be formed by moulding, such as injection moulding, and may be rigid or semi-rigid.

The unitary cover member 200 is removable from the mobile phone 1. In the embodiment shown, the unitary cover member 200 is removed by sliding the cover 200 along grooves 20, 21, 22 on the front 14 and/or back 15 surfaces of the body (see FIG. 1a). Only the front surface 14 is visible in FIG. 1a, and therefore equivalent grooves 20, 21, 22 on non-visible rear surface 15 are also not visible. The cover 200 remains in the grooves 20, 21, 22 at least by virtue of friction between the edges of the cover and the grooves within which the edges are inserted. This can at least be attributable to the fact that the cover is folded so that it wants to return to the flat unfolded configuration.

The edge 13 of the phone 10 is curved to correspond with the curvature of the cover 200 against which it will abut.

The cover 200 could also have cut outs (not shown) so that it can push over corresponding male features in the grooves 20, 21, 22.

One or more crease/fold lines (not shown) may be provided to allow the cover 200 to be easily bent into shape along pre-determined lines. For example, two parallel fold lines could be provided to allow the cover to be folded back onto itself.

As shown in FIG. 1a, the front surface 14 of the body 1 includes a keypad 30 and/or a display 31. The unitary cover member 200 may include a transparent portion 231. This is positioned on the planar member 200 for alignment with the display 31 in the folded cover configuration. The unitary cover member 200 also includes flexible key actuation portions 230 positioned to be aligned with keys of the keypad 30 in the folded cover configuration.

The cover 200 is made from a flexible translucent/transparent film material, such as polycarbonate. Advantageously, the reverse of the material is printed so that the printed reverse is hidden away from abrasion during use.

An advantage of the invention is that the unitary bendable cover member 200 can be used to replace the two A and B covers of prior art mobile communications devices. The unitary cover is cheap to make with minimal tooling. The cover 200 can be readily distributed in the flat configuration, for example, along with printed publications, such as magazines.

The cover 200 may replace covers A and/or B or be used to overlie on the A and/or B covers. In the case that it is used to overlie on the A and/or B, the A and or B covers would preferably have grooves to allow the cover 200 to be held in place.

The cover 200 may also have an adhesive to attach to the mobile phone. This may be a user-releasable adhesive such as that used on Post-It™ notes.

The cover 200 may have one or more apertures (not shown) thorough which features of the mobile phone may extend. For example, a joystick/ball or other input key.

Various different covers can be manufactured relatively cheaply and give the mobile phone user interface a different personalised look. It is also possible to adapt the printing on the cover to suit a particular software application which is run on the mobile phone. Thus, when a user uses the phone for game A, he can have a specific cover which indicates the functions performed by specific keys. In the case of when the phone is used to make a voice call, the user can use a different cover specifically adapted for that usage. The covers may also have raised domes to activate only certain keys. The raised domes are arranged to activate keys disposed underneath. These keys are those which are used for a particular application run on the phone. The other keys which are not used for running the application may not have raised domes. Therefore, activation is avoided.

It will be appreciated that various modifications can be made to the invention without departing from the scope of the present invention. For example, the cover could be folded over edge 12 rather than 13. Additionally, two such bendable sheets could be used; one for the front as shown in FIG. 1a and the other down side 12 as suggested above. The cover may have one or more apertures. These may assist with holding the cover on the mobile phone.

1. An electronic device cover formed from a sheet of material dimensioned to at least partially cover an electronic device, wherein the sheet is configured to have a substantially flat configuration and a folded configuration and be bendable into the folded configuration to cover the electronic device.

2. A cover according to claim 1, wherein the cover is user bendable onto an electronic device.

3. A cover according to claim 1, wherein the cover is user replaceable onto an electronic device.

4. A cover according to claim 1, wherein the cover is in the folded configuration.

5. A cover according to claim 1, wherein the cover is in the flat configuration

6. A cover according to claim 1, wherein the sheet of material is formed from a plastic.

7. A cover according to claim 1, wherein the sheet of material is formed from a metal.

8. A cover according to claim 1, wherein the sheet of material comprises metal and/or plastic.

9. A cover according to claim 1, wherein the sheet of material is bendable back on itself.

10. A cover according to claim 1, wherein the sheet of material is dimensioned to bridge one or more lateral edges of an electronic device.

11. A cover according to claim 1, wherein the sheet of material is dimensioned to cover a front and/or rear surface of the electronic device.

12. A cover according to claim 1, wherein the sheet of material comprises a folding line to assist the folding of the sheet into the folded configuration.

13. A cover according to claim 1, wherein the sheet of material comprises a holding arrangement to facilitate the holding of the cover on the device in the folded configuration.

14. A cover according to claim 1, wherein the sheet of material is printed on the inner folded surface of the cover.

15. A cover according to claim 1, wherein the sheet of material is arrangable to be folded in half.

16. A cover according to claim 1, wherein the sheet of material is printed to provide user readable indicia.

17. A cover according to claim 1, wherein the sheet of material comprises one or more actuators to engage with a covered user interface of an electronic device.

18. A cover according to claim 17, wherein the one or more actuators have sufficient flexibility to allow movement of the actuators in/out of the plane of the sheet.

19. A cover according to claim 17, wherein the one or more actuators are raised domes.

20. A cover according to claim 1, having a reeled configuration for facilitating transport, storage, and/or packaging of the cover.

21. A cover according to claim 1, dimensioned and configured to cover a mobile phone.

22. A method of distributing a printed publication with a cover according to claim 1.

23. An electronic device arranged to receive an electronic device cover formed from a sheet of material dimensioned to at least partially cover the electronic device, wherein the sheet is configured to have a substantially flat configuration and a folded configuration and be bendable into the folded configuration to cover the electronic device.

24. (canceled)

25. (canceled)

26. (canceled)
